(19) United States
(12) Patent Application Publication
(10) Pub. No.: US 2014/0370203 A1
(43) Pub. Date: Dec. 18, 2014

(54) MICRO COLD SPRAY DIRECT WRITE SYSTEMS AND METHODS FOR PRINTED MICRO ELECTRONICS

(71) Applicant: NDSU RESEARCH FOUNDATION, Fargo, ND (US)

(72) Inventors: Robert A. Sailer, West Fargo, ND (US); Justin M. Hoey, Fargo, ND (US); Iskander Akhatov, West Fargo, ND (US); Orven Swenson, Fargo, ND (US); Artur Lutfurakhmanov, Ufa (RU); Michael Robinson, Rapid City, SD (US)

(73) Assignee: NDSU RESEARCH FOUNDATION, Fargo, ND (US)

(21) Appl. No.: 14/333,124

(22) Filed: Jul. 16, 2014

Related U.S. Application Data
(63) Continuation of application No. PCT/US2013/023320, filed on Jan. 25, 2013.
(60) Provisional application No. 61/591,365, filed on Jan. 27, 2012.
(60) Provisional application No. 61/691,112, filed on Aug. 20, 2012.

(51) Int. Cl. H05K 3/14; H05K 3/10

(52) U.S. Cl. CPC H05K 3/146; H05K 3/102; H05K 2203/1344; H05K 2203/0502
USPC 427/455; 239/418; 239/135

(57) ABSTRACT

A system and method for depositing an aerosolized powder of solid particles on a substrate for printed circuit applications is disclosed and comprises cold spraying the aerosolized powder onto the substrate to form a finite feature, wherein at least one of the dimensions of length and width of the finite feature measures 500 microns or less.

### CROSS-REFERENCE TO RELATED APPLICATIONS

This application is a 35 U.S.C. §111(a) continuation of PCT international application number PCT/US2013/023320 filed on Jan. 25, 2013, incorporated herein by reference in its entirety, which claims priority to, and the benefit of, U.S. provisional patent application Ser. No. 61/591,365 filed on Jan. 27, 2012, incorporated herein by reference in its entirety, and which claims priority to, and the benefit of, U.S. provisional patent application Ser. No. 61/691,112 filed on Aug. 20, 2012, incorporated herein by reference in its entirety.

The above-referenced PCT international application was published as PCT International Publication No. WO 2013/158178 on Oct. 24, 2013, and republished on Jan. 30, 2014, which publications are incorporated herein by reference in their entireties.

### STATEMENT REGARDING FEDERALLY SPONSORED RESEARCH OR DEVELOPMENT

This invention was made with Government support under Contract No. H94003-09-2-0905 with the U.S. Defense Microelectronics Activity (DMEA). The Government has certain rights in the invention.

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to direct write fabrication methods and devices, and more specifically, to the focusing of particles emitted from deposition heads or tips used for direct write fabrication.

2. Description of Related Art

Second level of packaging, i.e. fabrication of the printed circuit board, constitutes a major part in the manufacturing of an electronic device. Its primary functions include providing a mounting surface for components, providing input/output pads, or via holes, for components, providing interconnects for inter-component interactions, providing probe points for circuit board testing, supporting manufacturing operations by providing identification points during assembly and identification points for support during field maintenance and service.

Several serial as well as parallel technologies have been developed to print interconnects at the second level of packaging on rigid and flexible substrates. Copper etching and screen printing are the most commonly used parallel processes for fabrication of interconnects at the second level of packaging. The feature size of the copper etching process is generally limited to 50 μm. The etching process involves the use of several chemicals which may not be compatible with many polymeric substrate materials.

The feature size of the screen printing process is limited to 100 μm, and the printing of smaller features may require the use of special screens. Some existing methods have been able to print 50 μm wide lines using a very complicated screen printing process in which the mask for printing was inks used for screen printing have metal flakes as large as 15 μm, which makes it nearly impossible to print conductive features smaller than 50 μm consistently. Also, parallel processes waste inks and conductive material and the smallest design changes require new masks or screens. These parallel processes are also not capable of filling via holes therefore additional syringe based processes are used to fill via holes which increases manufacturing cost.

A number of direct write (serial) processes have been developed to address limitations of parallel processes. The Maskless Mesoscale Material Deposition (M3D®) process uses an aerosol beam of conductive nano inks to print features on a substrate. A variant of the M3D® process, the Collimated Aerosol Beam Direct Write Deposition (CAB-DW) method uses a combination of converging and diverging nozzles to deposit silver nano inks to print features. The Inkjet printing process forces droplets of ink through a micro capillary on to a substrate. Syringe based direct write technologies use a “micropen” to print conductive trace patterns on a substrate. All of the above direct write processes use nano inks, which need an additional sintering step in order to make the features electrically conductive. Often, the sintering temperature is greater than the glass transition temperature of polymeric substrates, making it unsuitable for low cost flexible electronic devices. Moreover, the inks are unsuitable for via hole filling, as there is a shrinkage of the ink when it is thermally sintered as the solvent of the ink evaporates.

A number of laser based direct write methods have also been developed. The Matrix Assisted Pulsed Laser Evaporation Direct Write (MAPLE-DW) method is used to transfer small amounts of evaporated material from a transparent source to a receiving substrate using a laser. In the Laser Micro Cladding Electronic Paste (LMCEP) process, a laser is selectively irradiated on a substrate coated with epoxy paste containing conductive material. Later on the uncured paste is washed away in order to obtain a conductive pattern. However, the introduction of lasers in the manufacturing process will substantially increase the cost of manufactured products.

The cold spray or kinetic spray material deposition method was first discovered in the early 1980s while studying two-phase supersonic flow in a wind tunnel. It was observed that if a particle in the flow stream impacted a surface above a certain critical velocity, the particle will undergo instant plastic deformation and make a splat on the surface, often adhering very strongly to the solid surface. The critical velocity required to make the splat is dependent on the material of the particle.

The cold spray deposition process has been used exclusively as a surface coating method (coating large areas), but has not been used to create small, defined features such as those required in the direct write process for microelectronic applications.

Fine feature deposition has been developed using thermal spray with a high temperature plasma plume, see U.S. Pat. No. 6,576,861. Features as small as 75 microns have been reported. However, this deposition method relies on a high temperature plasma torch. This makes it inappropriate for thermally sensitive substrates such as those used in flexible microelectronics, and solar applications. In addition, this process uses physical collimators for masking of the deposition pattern to achieve feature size.

Accordingly, an object of the present invention is a cold spray deposition process that focuses beam deposition for direct write of printed microelectronics applications.

### BRIEF SUMMARY OF THE INVENTION

The present invention is directed to deposition of metallic features having small dimensions at only slightly elevated temperatures. The present invention comprises a system and method configured to direct write metallic lines using metallic powder precursors. This deposition system and method of the present invention may be performed on temperature sensitive substrates at a high deposition rate.

The system and method of the present invention involves using separate gas flows (carrier and accelerator), where the ratio and quantity of gases and preheat temperatures may be optimized to obtain maximum focusing of the powder stream through a micro nozzle. When properly focused and accelerated, features as small as 10 microns will be possible, with line width primarily limited by the focusing characteristics of the system and the primary precursor particle size. The nozzle for this system may be either subsonic, or supersonic with nozzle throat diameter foreseen to be between 50 and 500 microns. This technology has application in microelectronics for writing interconnects and other metallic features, and solar cell applications for the direct write of the top metallization layer. A key advantage of this process results from depositing a metallic line without the need for sintering, or further post processing, while still achieving near bulk conductivity.

Another aspect is a cold spray process as a direct write technology for printed microelectronics applications. Using the cold spray process of the present invention, aluminum, tin and copper particles with sizes varying from 0.5 μm to 5 μm diameter were deposited on glass, silicon, BT, PEEK, polyimide, Teflon, PES, LCP, Teslin, FR4 and Mylar. Lines as small as 75 μm have been printed and via holes as small as 75 μm have been filled by optimization processing parameters and nozzle geometry. Further deposition head embodiments enabled printing of 50 μm features after using appropriate processing parameters. The average bulk resistivity values of copper, tin and aluminum were typically 4.4 μΩ-cm, 28 μΩ-cm and 4.08 μΩ-cm respectively.

Another aspect of the present invention is a nozzle configuration with a converging-radius section leading into a section of constant radius, which allows for the creation of fine features with a minimal size.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic diagram illustrating the micro cold spray direct-write system of the present invention.

FIG. 2 is a schematic cross section view illustrating the internal geometry of the deposition head of FIG. 1.

FIG. 3 shows an image of copper lines deposited on glass (Left) without flow cone; (Right) with flow cone in the deposition head.

FIG. 4A-FIG. 4C show cross-sectional SEM images of copper lines deposited on silicon with 50 psi pressure, 80 psi pressure, and 110 psi pressure, respectively.

FIG. 5 is an SEM image of a 150 μm diameter via hole filled with copper in accordance with the present invention.

FIG. 6 is an SEM image of 150, 100 and 75 μm via holes filled with aluminum copper in accordance with the present invention.

FIG. 7A and FIG. 7B show high resolution cross-sectional SEM images of aluminum lines deposited on silicon illustrating desirable and undesirable microstructure.

FIG. 8A and FIG. 8B show images of 2 μm particle trajectories exiting a nozzle of the prior art.

FIG. 9 shows a nozzle configuration in accordance with the present invention.

FIG. 10 shows a simulation of aerosol particles, 2 μm diameter, flowing through the converging-constant radius nozzle having a 400 μm inlet and 100 μm outlet.

FIG. 11 is a scanning electron microscope (SEM) image of 4 μm silica powder for experimental aerosol flows on carbon-tape.

FIG. 12 is a graph of beam width vs. distance from the nozzle exit for a linearly-converging 200 μm nozzle, and a 161 μm converging alumina (ceramic) nozzle compared to theory using only Stokes force.

FIG. 13 is a graph of beam width vs. distance from the nozzle exit for a 161 μm converging alumina (ceramic) nozzle with 200 μm straight section of length 11.84 mm, 17 mm, and 30 mm.

### DETAILED DESCRIPTION OF THE INVENTION

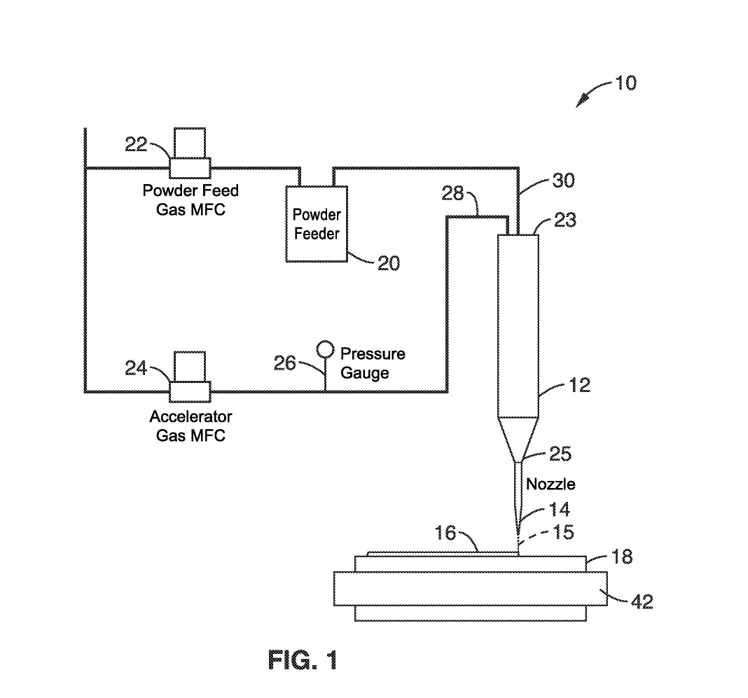

FIG. 1 is a schematic diagram illustrating a Micro Cold Spray (MCS) system 10 for direct write deposition of features for printed electronic applications in accordance with the present invention. This system 10 impacts a high velocity aerosol beam 15 on a substrate 18 where the solid particles deform as they impact the substrate and stick, creating a near-continuous metallic feature 16. In a preferred embodiment, the metallic feature comprises a conductive interconnect for second level packaging of micro electronics. The metallic feature may be printed onto the substrate with a line width less than 500 μm, and preferably ranging from 1 μm to 500 μm, and preferably between 5 μm and 100 μm, and more preferably between 10 μm and 50 μm.

The system 10 may also be used to print insulating or semiconducting features using any solid material, so long as the material is malleable. Examples of these materials include, but are not limited to, polymers such as Polyethylene, polypropylene, polymethylmethacraylate, polysulfone, polyethers, polyketones, polytetroflouroethylene, poly vinyldiene, poly 3-hexylthiophene, and related materials.

Helium is introduced into a powder feeder 20 with a constant flow rate that is governed by a powder feed gas mass flow controller (MFC) 22. The precursor material (dry particles preferably comprising a metallic composition) is aerosolized in the powder feeder 20 and is carried into a proximal input end 23 the deposition head 12 via line 30. For purposes of this description, the flow in line 30 from powder feeder 20 is referred to as the carrier gas flow f_{c}.

A second stream of helium 28 is introduced into the proximal input end 23 of deposition head 12 to accelerate the particles within carrier gas flow f_{c}. For purposes of this description, the flow in line 28 is referred to as the accelerator gas flow fₐ. The accelerator gas flow fₐ in line 28 is covered by accelerator gas MFC 24, and feedback for the line is provided by pressure gauge 26.

Deposition head 12 has a nozzle 14 at its distal or output end 25 that is configured to focus the metal particles that emerge from the nozzle 14 and deposit them on substrate 18, thereby forming conductive trace 16. The deposition head 12 may be maneuvered using a simple X-Y-Z robot (not shown) or an XYZ stage 42 coupled to the substrate 18.

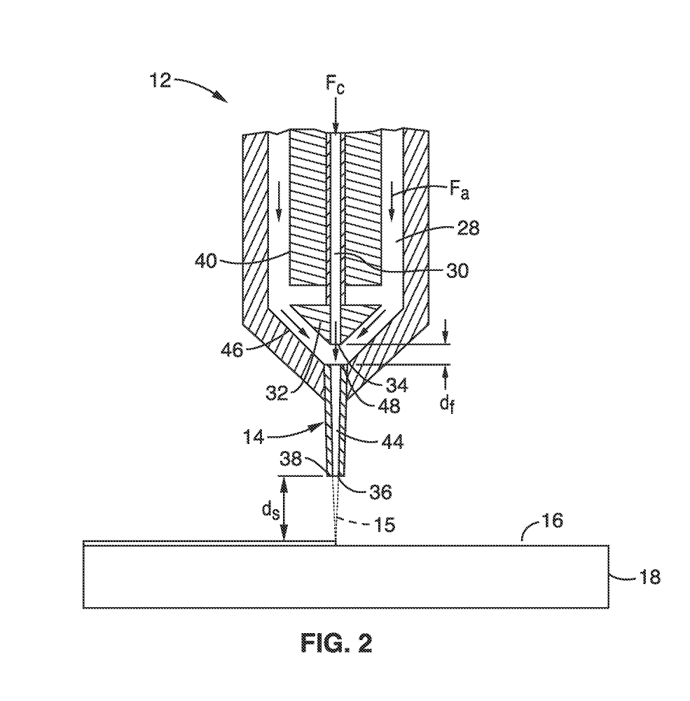

FIG. 2 illustrates a detailed sectional view of the distal end of deposition head 12. The deposition head 12 comprises a concentrically located line 30 that feeds the carrier gas f_{c}. The accelerator gas f_{c} is split into lateral lines (or one annular line) 28 that are disposed a spaced apart distance from the central line 30. Lines 28 converge at a tapered section 46 defined by wedge or flow cone 32. In the embodiment where channel 28 is annular, the wedge/flow cone 32 and channel 46 form a conical path to the exit port 34 of carrier gas line 30, with terminates at an apex of the conical channel 46.

As seen in FIG. 2, the exit port 34 is held a distance d_{f} above the neck 34 of nozzle 14 to allow for the accelerator gas flow fₐ to integrate with and accelerate the carrier gas f_{c} into the converging channel 44 of nozzle 14. Distance d_{f} is optimally sized (approximately 1 mm in length, however other lengths are contemplated) to promote proper distribution of the flow of particles into the nozzle 14. The nozzle 14 shown in FIG. 1 has a tapered or converging bore 44 that has a larger diameter at the entrance 48 and small diameter at the exit opening 36 (approximately 50 μm to 500 μm). The exit opening 36 is preferably spaced from the substrate 18 at a standoff distance dₛ ranging from 0.5 mm to 10 mm.

The deposition head 12 is heated to a predetermined temperature via heating element(s) 40 that is (are) disposed between the central line 30 and lateral line 28 in order to compensate for the drop in temperature of helium as it goes through the converging nozzle 14 and achieves a choked flow condition at the nozzle entrance 42. A rough estimate of the drop in temperature through the nozzle 14 may be determined using the equations of quasi one-dimensional isentropic flow of an ideal gas through a duct with varying area of cross-section.

The gauge pressure is the static pressure in the deposition head 12 as measured by the pressure gauge 26 shown in FIG. 1. Carrier gas flow rate and accelerator gas flow rate are defined as volumetric flow rate as measured by MKS 100B mass flow controllers 22 and 24 for the carrier gas f_{c} and accelerator gas fₐ respectively. The flow rate is set to generate an exit velocity of the deposited dry particles according to the specific particulate being used. Typical velocities range from 200 m/s to 1000 m/s, e.g. 250 m/s for lead particles, to 500 m/s for copper.

Experiment #1 Setup

Two prototype MCS deposition heads were built. A first prototype test MCS deposition head built without a flow cone, and one built with a flow cone 32 as illustrated in FIG. 2. It was shown that introduction of the flow cone in the second prototype demonstrated a significant decrease in feature size and overspray in lines printed. A linearly converging nozzle 14, as depicted in FIG. 2, with an inlet 48 diameter of 1 mm, exit or throat diameter of 200 μm, and length of 19 mm was used for this set of experiments. For varying the gauge pressure, the carrier gas flow rate was kept constant at 800 cm³/minute and the accelerator gas flow rate was varied between 2200 cm³/minute to 14000 cm³/minute which resulted in a gauge pressure at inlet 48 of the nozzle 14 of 50 psi to 90 psi.

Using appropriate deposition conditions, copper, aluminum and tin particles with size varying between 0.5 μm-5 μm were deposited on glass substrates. The average height of the lines was measured using a KLA Tencor's P-15 Longscan Stylus Contact Profiler, the width of the lines was measured using an Olympus optical microscope, and resistance of the line was measured using Agilent Technologies B1500A Semiconductor Device Analyzer. Convenience sampling was used for resistivity measurement.

In another set of experiments, copper, tin and aluminum powders were printed on glass, silicon, BT, PEEK, polyimide, Teflon, PES, LCP, Teslin, FR4 and Mylar substrates. In order to study the compatibility of the powder with substrate material, the lines printed were characterized for bulk resistivity and examined visually under the microscope. In another set of experiments, lines were printed by varying the nozzle geometry and modifying the appropriate processing parameters.

Experiments were also carried out to investigate the efficacy of using the MCS deposition process of the present invention to fill via holes. Via holes of size 150 μm, 100 μm and 75 μm were micromachined on a sapphire die of thickness 200 μm. The die was secured on a fused silica glass slide and a magnifying glass was used to align the nozzle of the MCS deposition head on the via hole. The powder flow rate was set to a high value and the head was slowly traversed over the via. The filling of the via holes were characterized using optical microscopy.

Experiment #1 Results

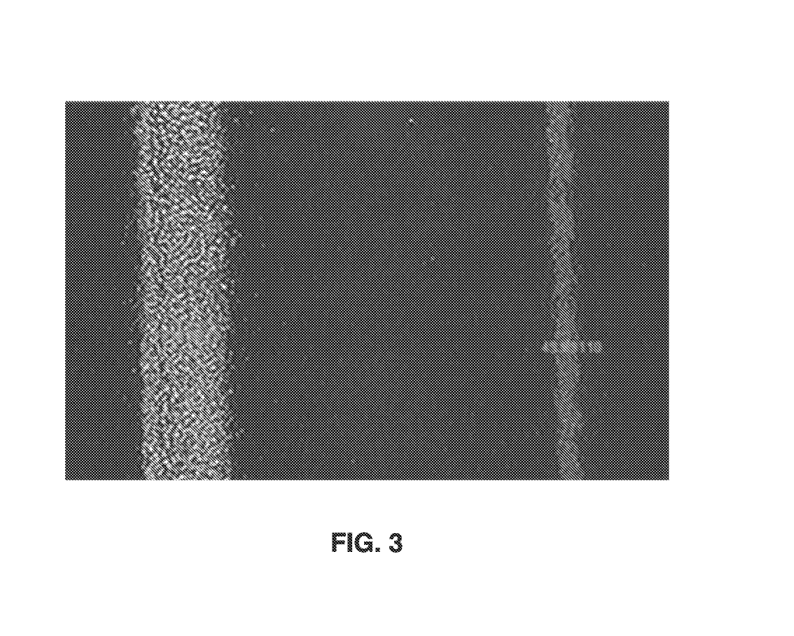

Bulk resistivity values for copper, tin and aluminum were typically 4.4 μΩ-cm, 28 μΩ-cm and 4.08 μΩ-cm respectively. After having an estimate of the effect of processing parameters on line geometry, nozzles 14 of smaller throat diameter were used to print features by modifying the processing parameters. FIG. 3 illustrates the difference in feature size from the first deposition head prototype (no flow cone 32) and when the flow cone 32 was introduced in the second deposition head prototype. Using a carrier gas flow rate of 400 cm³/minute, gauge pressure of 110 psi, standoff height dₛ of 0.5 mm, flow cone height d_{f} of 1 mm, and a substrate 18 velocity of 1 mm/second, lines as small as 50 μm were printed using a nozzle 14 with a throat 36 diameter of 100 μm, thus showing a focusing of the deposited particles 16 beyond the nozzle exit 36. The resistivity of these lines was calculated to be 1.9 μΩ-cm while to the bulk resistivity of pure copper is 1.68 μΩ-cm. This demonstrates the capability of the MCS direct-write system 10 to print features with conductivity up to 90% of the bulk metal.

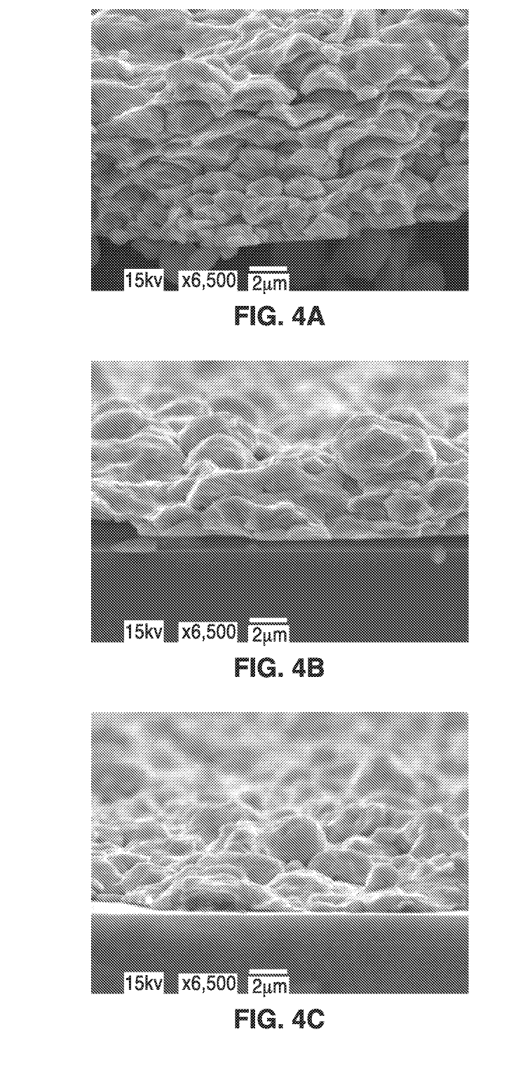

FIG. 4A through FIG. 4C show high resolution SEM images of cross-sections of copper lines printed on silicon substrate using different gauge pressures. At a low pressure of 50 psi (FIG. 4A), the copper particles splat on top of each other, forming a multilayered coat with high porosity. If the pressure is increased to 80 psi (FIG. 4B), the velocity, and hence energy, of the particles is also increased. This results in a higher energy impact which reduces the porosity of the copper deposit. At a high pressure of 110 psi (FIG. 4C), the porosity of the features decreases, however, the layer thickness of copper in the coating also decreases.

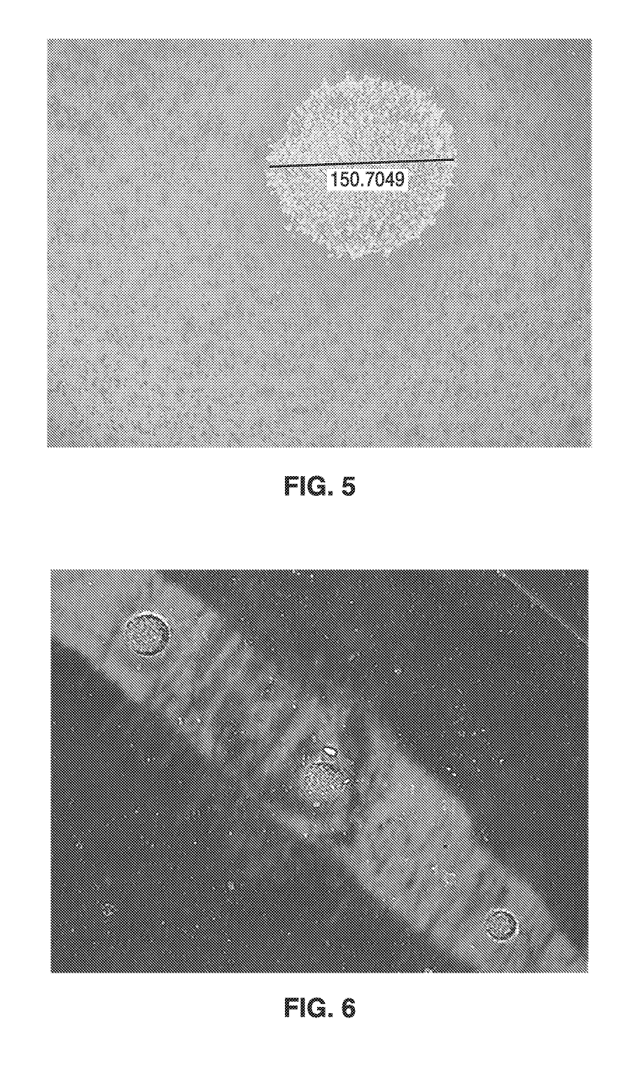

In another set of experiments via holes of varying sizes were filled with copper and aluminum powder. FIG. 5 illustrates a via hole of 150 μm, and FIG. 6 illustrates via holes of 150 μm, 100 μm, and 75 μm, all filled using the MCS direct-write process of the present invention. The image in FIG. 5 is taken from the “bottom” side of the via placed on a glass slide. Initial attempts to remove the vias from the glass were unsuccessful, as the deposition was very well adhered to the glass substrate. When the die was lifted, the deposit remained adhered to the glass slide, and pulled a section out of the top contact line right above the via. Future attempts to remove the die were done by applying force to the side of the die. This caused the deposit to shear off the substrate. This clearly demonstrated that the MCS deposited material had very good adhesion to the substrate. In FIG. 6 with the via holes filled with aluminum powder, the 150 μm and 75 μm via holes look incompletely filled due to misalignment of the deposition head nozzle with respect to the via holes.

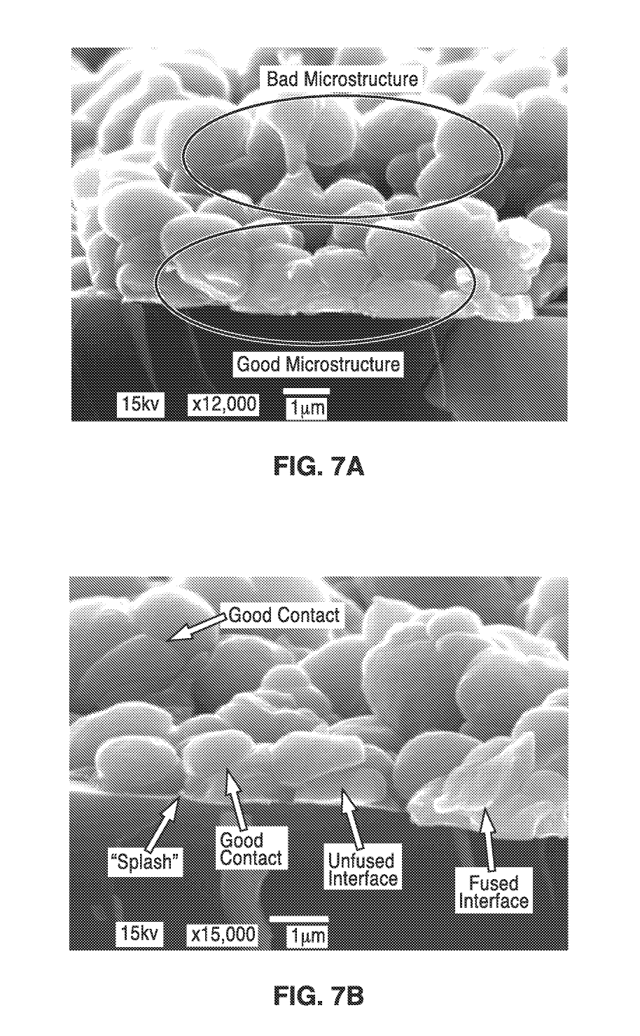

FIG. 7A and FIG. 7B show high definition SEM pictures of aluminum lines deposited on silicon substrate with varying gauge pressure in order to study the porosity and contact area between individual particles. Similar to the case of copper lines printed using different gauge pressure, aluminum lines printed with low gauge pressure had high porosity. Lines printed with very high gauge pressure showed low porosity thin layers of metal deposited.

Ideally, in order to obtain high conductivity in a line, the porosity should be minimal and the effective area of contact between the metal particle should be maximal. FIG. 7A and FIG. 7B illustrate that a mixture of good as well as bad contacts were obtained on an individual line. The particles that hit the surface directly made a “splat” and therefore contributed to the adhesion of the line to the substrate. The particles that impacted on other aluminum particles and made a fused interface had good microstructure with low porosity, while the particles that had unfused interface with other particles had bad microstructure with high porosity leading to high bulk resistivity. It may be noted that such mixed interfaces are expected if the MCS deposition process is not optimized.

Experiments were performed in order to study the effect of processing parameters on line geometry. Tin powder was deposited on silicon substrate with gas temperature of 200° C. with gauge pressure varying between 25-60 psi. Raising the system above 200° C. led to the clogging of the nozzles as the melting point of tin is 231° C. It was observed that by carefully optimizing the gauge pressure, triangular area of cross-section can be obtained. The bulk resistivity of the tin lines varied from 27.2 μΩ-cm to 70 μΩ-cm, which is roughly 2-6 times the theoretical bulk resistivity of tin. Also, as discussed above, from a close examination of the particles in the substrate-particle interface indicates that microstructure of the line is the best near the substrate.

Finally, experiments were carried out to deposit tin, copper and aluminum particles on different substrates. Table 1 shows all combinations of metals and substrates that were tested. A “Yes” indicates that deposition of a mechanically continuous line was successful, but the line may not have been conductive. A “No” indicates that this combination has not yet yielded a mechanically continuous line. Tin exhibited good adhesion with glass and silicon rigid substrates, however, it displayed poor deposition efficiency on most flexible substrates. Aluminum and copper displayed good compatibility and disposition efficiency with most flexible and rigid substrates.

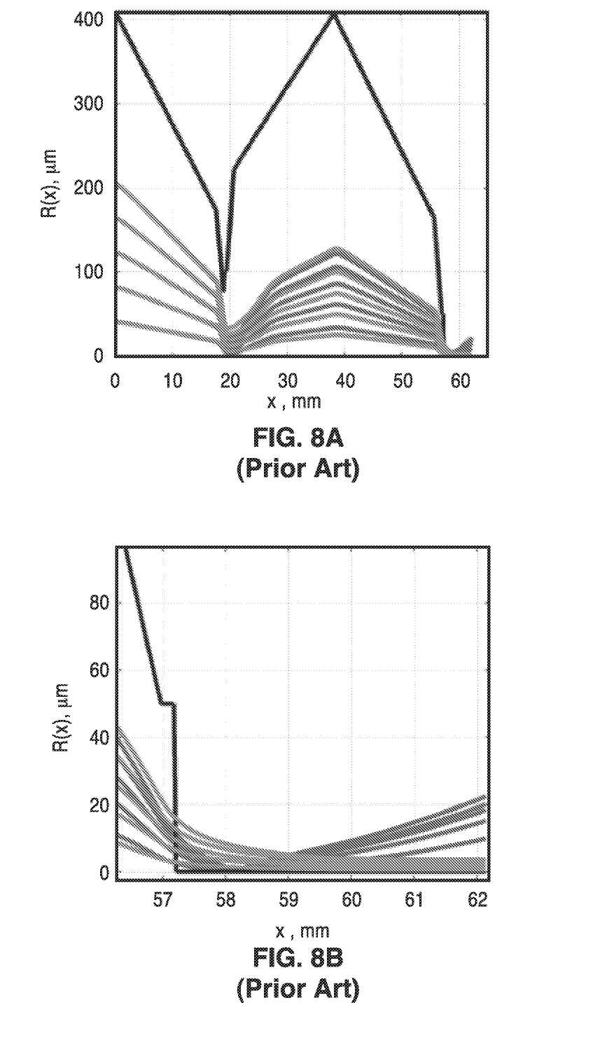

Referring now to FIG. 8A through FIG. 13, an improved nozzle configuration was developed for use in aerosol print methods such as the micro cold spray (solid particle) direct-write system 10 of FIGS. 1 and 2, as well for use in CAB-DW (liquid droplet) systems.

FIG. 8A and FIG. 8B show resulting plots of an investigation into the trajectories of aerosol particles through a CAB-DW nozzle, which revealed that the calculated beam widths are greatly affected by the applied forces. Shown in FIG. 8A are the results of this modeling with FIG. 8B being a close-up view at the nozzle exit. The nozzle profile is shown in black, while trajectories of the particles with Stokes and Saffman force applied are shown in dark grey, while the trajectories for only Stokes force applied are shown in light grey. The results of the simulation using 2 μm particles show a large deviation in the trajectories with and without Saffman forces applied. A focal point at approximately 1.25 mm past the nozzle exit occurs with Saffman force applied, while excellent collimation occurs with only Stokes force applied.

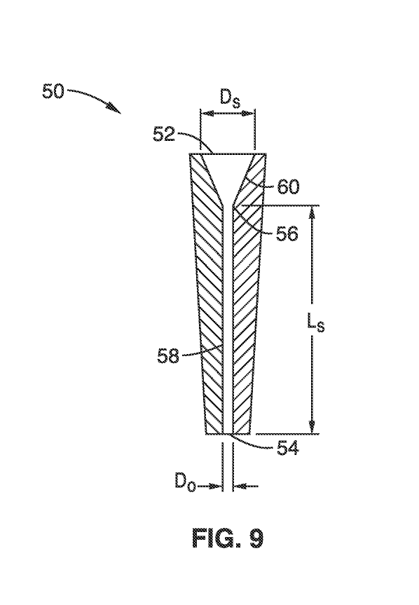

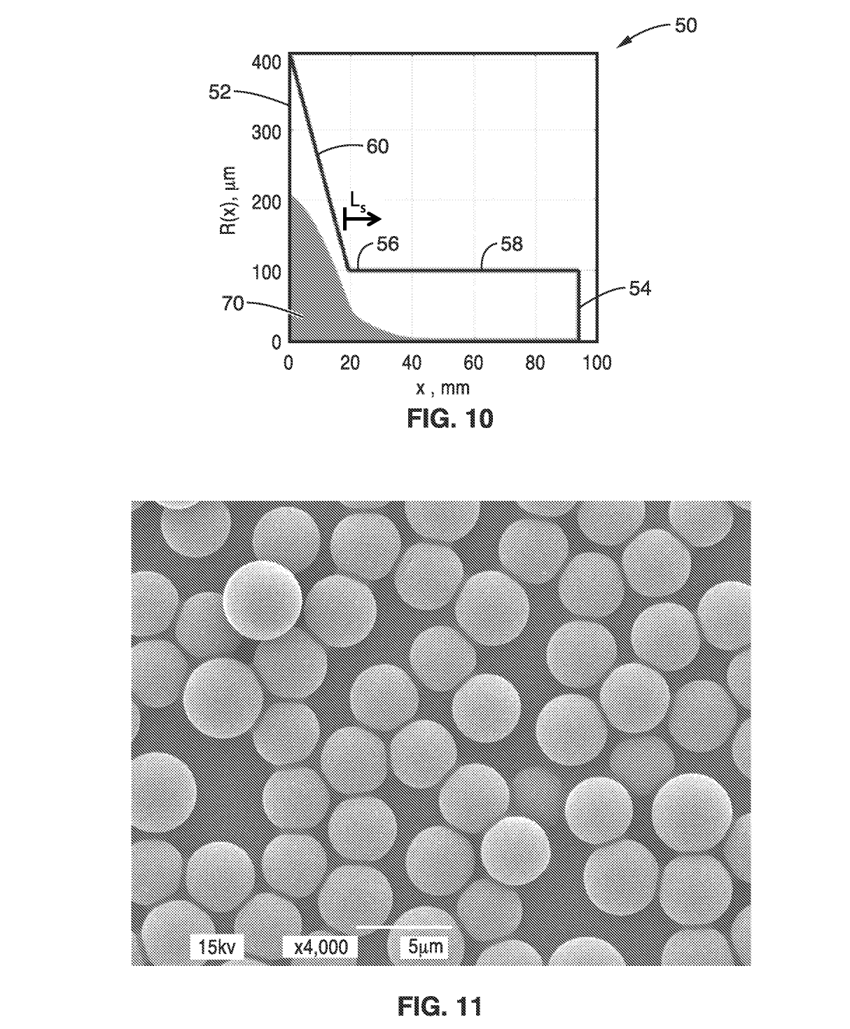

FIG. 9 and FIG. 10 show an improved nozzle 50 configured to generate a smaller, more collimated, beam width. FIG. 9 shows a cross-sectional view of the nozzle 50, while FIG. 10 shows one side of the profile of the inner surface 56 of the nozzle 50 (by revolving the profile in FIG. 10 about the x-axis, the inner surface 56 of nozzle 50 in FIG. 9 is obtained). As seen in FIGS. 9 and 10, inner surface profile 56 incorporates a converging conical section 60 having an entrance diameter of Dₛ of approximately 400 μm leading into a constant diameter, or cylindrical section 58 having a length Ls and diameter Dₒ of approximately 100 μm.

Aerosol particles 2 μm in diameter, with a density of 1.1 g/cm3, appear to focus using this nozzle geometry at a total flow rate of 240 ccm. The length of straight section, Ls, in FIG. 10 is 75 mm. It is appreciated that a shorter length nozzle may also be contemplated. As can be seen in FIG. 10, the aerosol particles 70 are focused well before the end of the nozzle 54 at Ls ˜20 mm, which leads to the hypothesis that a shorter nozzle may produce near-equal quality beam characteristics for these specific flow parameters.

Experiment #2 Setup

One challenge that arises from interpreting experimental results is the difficulty in knowing the exact particle size. To reduce this unknown, a powder feeder was incorporated that uses a high velocity gas jet in combination with an electromagnetic actuator to feed powder at flow rates as low as 40 ccm, with a mass of powder as small as 250 mg. For this work, 3.8 μm nominal diameter near-spherical silica powder (Cospheric Inc., Santa Barbara Calif., USA, part # SiO2MS-4 um) which has a CV<10% and a 99% degree of roundness was used. An SEM image of the silica particles is shown in FIG. 11. It is evident that these particles indeed are both near spherical, and about 4 μm in diameter. In some instances, the particles appear to have flattened features, but this is merely a consequence of the conductive carbon tape used to secure the particles for imaging.

Experiment #2 Results

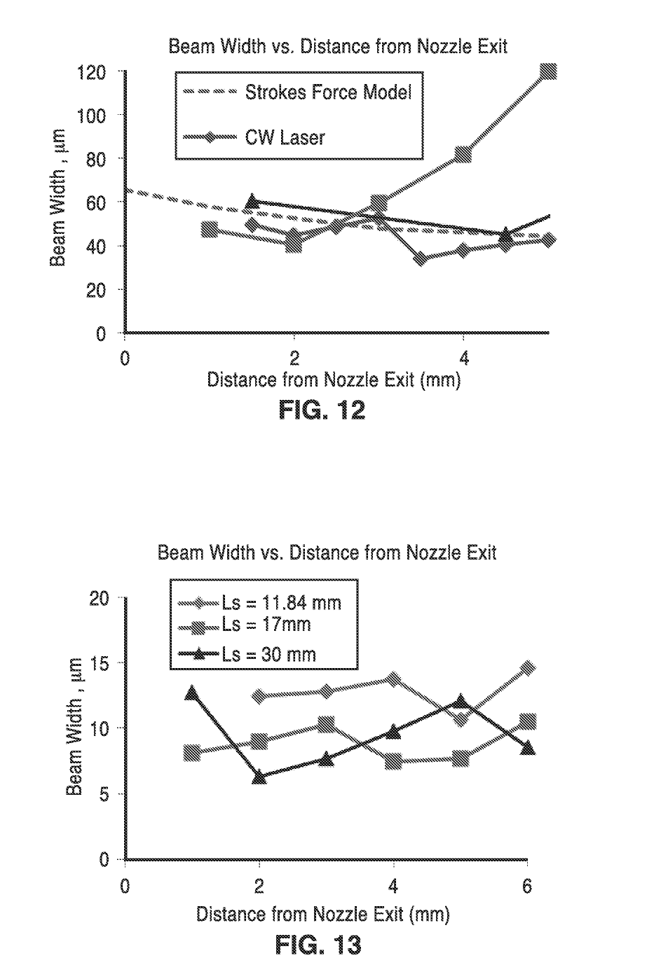

FIG. 12 show a plot of results of beam width measurements for both a tungsten carbide linearly-converging nozzle (800 μm inlet diameter to 200 μm exit diameter), as well as an alumina (ceramic) converging nozzle with an inlet diameter also of 800 μm, and exit diameter of 161 μm. Both nozzles had a length of 19.05 mm. These experimental results are for the 3.8 μm silica powder with a total flow rate of 120 ccm N2 (60 ccm carrier gas, and 60 ccm sheath gas). Beam width was measured using both shadowgraphy and laser scattering methods and calculated using Full-Width-Half-Max (FWHM, 50%) intensity levels as the cutoff for the edge of the aerosol beam. The theoretical beam width using only Stokes force of fluid-particle interaction is also displayed in FIG. 12. The beam widths match very well for both methods of measuring beam width, as well as to the theoretical data. This gives creed to the accuracy of the model developed and also shows that the ceramic nozzle can achieve similar beam widths to the linearly converging ones.

Preliminary data has experimentally been obtained for the beam width of aerosol particles exiting a near-linear converging nozzle followed by a straight section as detailed in the nozzle 50 of FIG. 9 and FIG. 10. For this test, an alumina nozzle with 161 μm final diameter, and 19.05 mm length was used to approximate the converging section 60. Tungsten carbide sections with lengths Lₛ of 11.84 mm, 17 mm, and 30 mm, with 200 μm diameter were employed for the straight section 58. Beam widths were calculated from 1 mm to 6 mm from the nozzle exit 54 using the CW laser approach and are displayed in FIG. 13. The flow rate for these experiments was identical to those used previously (60 ccm carrier gas, 60 ccm sheath gas).

As shown in FIG. 13, beam width results of the converging-straight nozzle design similar to nozzle 50 shown in FIGS. 9 and 10 are dramatically improved from that of just a converging nozzle (e.g. nozzle 14 of FIG. 2). Minimum beam width decreases from 40 μm for the 161 μm converging nozzle to just 6 μm for the 161 μm converging nozzle, with a 30 mm straight section attached. An additionally impressive characteristic of the nozzle 50 is that the beam widths are very near, or substantially, collimated for any length nozzle. This may be beneficial for printing in that the nozzle-substrate distance will be less critical as compared to a more focused beam. The trend in beam width decreases as the length of the straight section increases, but it appears that only a 17 mm straight section would be required, as the beam width is nearly the same between the 17 mm and 30 mm sections.

The cold spray technology as a direct write technology has several advantages over the above mentioned direct write technologies. The metal powers can be deposited on a rigid as well as flexible substrate without the need for post processing therefore making is suitable for use on low temperature substrates. Secondly, cheaper alternatives of metal powders can be used (such as copper, aluminum, and tin) instead of expensive powders such as gold and silver. There is no shrinkage of the deposited features as there are no solvents being used during the deposition process. Moreover, the same deposition process can be used for printing interconnects as well as via hole filling.

It is appreciated that the micro cold spray direct-write system illustrated in FIGS. 1 and 2 may also be used in conjunction with CAB-DW (collimated aerosol beam—direct write) nozzles in place of nozzle 14, as described in pending U.S. patent application Ser. No. 12/192,315, which was published as U.S. patent application publication number US 2009/0053507 A1 on Feb. 26, 2009, the disclosure of which is incorporated herein by reference in its entirety. This technology could be used for high throughput direct write of microelectronics interconnects, solar cell top contacts (metallization layer}, and embedded sensor applications.

From the discussion above it will be appreciated that the invention can be embodied in various ways, including the following:

1. A micro cold spray direct-write system configured for deposition of solid particles on a substrate, comprising: a deposition head; a carrier gas supply line coupled to an input of the deposition head; wherein the carrier gas supply line is configured to carry aerosolized precursor material comprising solid particles; and an accelerator gas supply line coupled to the deposition head, the accelerator gas supply line configured to carry an accelerator gas to the deposition head; wherein the deposition head comprises a nozzle at an output of the deposition head; wherein the nozzle has an entrance opening and an exit opening; wherein the accelerator gas is configured to drive the carrier gas out of the exit opening of the nozzle as a high velocity aerosol beam such that the solid particles deform as they impact the substrate to generate a finite feature on the substrate.

2. A system as in any of the previous embodiments: wherein the deposition head comprises a first channel configured to deliver the carrier gas from the input along at least a length of the deposition head; wherein the first channel has an exit port that is spaced apart from the entrance opening of the nozzle to form a gap between the exit port and the entrance opening of the nozzle; and wherein the deposition head comprises a second channel configured to deliver the accelerator gas to the gap to integrate with the carrier gas.

3. A system as in any of the previous embodiments: wherein the particles comprise a metallic composition; and wherein the finite feature comprises a conductive feature on the substrate.

4. A system as in any of the previous embodiments, wherein the feature comprises a line having a width ranging from 1 μm to 500 μm.

5. A system as in any of the previous embodiments, wherein the feature comprises a line having a width ranging from 5 μm and 100 μm.

6. A system as in any of the previous embodiments, wherein the feature comprises a line having a width ranging from 10 μm and 50 μm.

7. A system as in any of the previous embodiments, wherein the aerosol beam at the exit opening has a velocity ranging between 200 m/s and 1000 m/s.

8. A system as in any of the previous embodiments: wherein the first channel is positioned substantially concentric with the nozzle; and wherein the second channel is configured to deliver the accelerator gas into the gap at an angle with respect to the carrier gas.

9. A system as in any of the previous embodiments: wherein the second channel forms a conical channel leading into the gap; and wherein the exit port of the first channel terminates at an apex of the conical channel.

10. A system as in any of the previous embodiments: wherein the nozzle comprises a tapered converging bore; and wherein the entrance opening of the nozzle has a larger diameter than the diameter of the exit opening.

11. A system as in any of the previous embodiments: wherein the nozzle comprises a tapered converging bore leading from the entrance opening of the nozzle; and wherein the tapered converging bore is followed by a substantially constant diameter bore leading to the exit opening of the nozzle.

12. A system as in any of the previous embodiments, wherein the diameter of the aerosol beam is focused to a diameter that is significantly smaller than the diameter of the exit opening of the bore.

13. A system as in any of the previous embodiments, wherein the aerosol beam is substantially collimated as it exits the exit opening of the nozzle.

14. A system as in any of the previous embodiments; wherein the aerosol beam is shaped in said bore prior to exiting the exit opening of the nozzle.

15. A system as in any of the previous embodiments, further comprising: a heating element disposed adjacent the first and second channels; wherein the heating element is configured to heat the carrier and accelerator gas to a predetermined temperature to compensate for a drop in temperature of carrier and accelerator gas as it is accelerated through the nozzle.

16. A micro cold spray direct-write deposition head configured for deposition of solid particles on a substrate, comprising: a first input for receiving a carrier gas; wherein the carrier gas comprises an aerosolized precursor material comprising solid particles; a second input for receiving an accelerator gas; and a nozzle at an output of the deposition head; wherein the nozzle has an entrance opening and an exit opening; wherein the accelerator gas is configured to drive the carrier gas out of the exit opening of the nozzle as a high velocity aerosol beam, such that the solid particles deform as they impact the substrate to generate a finite feature on the substrate.

17. A deposition head as in any of the previous embodiments, further comprising: a first channel configured to deliver the carrier gas from the input along at least a length of the deposition head; wherein the first channel has an exit port that is spaced apart from the entrance opening of the nozzle to form a gap between the exit port and the entrance opening of the nozzle; and a second channel configured to deliver the accelerator gas to the gap to integrate with the carrier gas.

18. A deposition head as in any of the previous embodiments: wherein the particles comprise a metallic composition; and wherein the feature comprises a conductive feature on the substrate.

19. A deposition head as in any of the previous embodiments, wherein the feature comprises a line having a width ranging from 1 μm to 200 μm.

20. A deposition head as in any of the previous embodiments, wherein the feature comprises a line having a width ranging from 5 μm and 100 μm.

21. A deposition head as in any of the previous embodiments, wherein the feature comprises a line having a width ranging from 10 μm and 50 μm.

22. A deposition head as in any of the previous embodiments, wherein the aerosol beam at the exit opening has a velocity ranging between 200 m/s and 1000 m/s.

23. A deposition head as in any of the previous embodiments: wherein the first channel is positioned substantially concentric with the nozzle; and wherein the second channel is configured to deliver the accelerator gas into the gap at an angle with respect to the carrier gas.

24. A deposition head as in any of the previous embodiments: wherein the second channel forms a conical channel leading into the gap; and wherein the exit port of the first channel terminates at an apex of the conical channel.

25. A deposition head as in any of the previous embodiments: wherein the nozzle comprises a tapered converging bore; and wherein the entrance opening of the nozzle has a larger diameter than the diameter of the exit opening.

26. A deposition head as in any of the previous embodiments: wherein the nozzle comprises a tapered converging bore leading from the entrance opening of the nozzle; and wherein the tapered converging bore is followed by a substantially constant diameter bore leading to the exit opening of the nozzle.

27. A deposition head as in any of the previous embodiments, wherein the aerosol beam is focused to a diameter that is significantly smaller than the diameter of the exit opening of the bore.

28. A deposition head as in any of the previous embodiments, wherein the aerosol beam is substantially collimated as it exits the exit opening of the nozzle.

29. A deposition head as in any of the previous embodiments; wherein the aerosol beam is shaped in said bore prior to exiting the exit opening of the nozzle.

30. A deposition head as in any of the previous embodiments, further comprising: a heating element disposed adjacent the first and second channels; wherein the heating element is configured to heat the carrier and accelerator gas to a predetermined temperature to compensate for a drop in temperature of carrier and accelerator gas as it is accelerated through the nozzle.

31. A deposition head as in any of the previous embodiments, wherein the finite feature comprises a deformable solid.

32. A deposition head as in any of the previous embodiments, wherein the finite feature comprises a polymer.

33. A deposition head as in any of the previous embodiments, wherein the polymer acts as an insulator.

34. A method for depositing an aerosolized powder of solid metallic particles on a substrate for printed circuit applications, comprising: cold spraying the aerosolized powder onto the substrate to form a finite feature; wherein at least one of the dimensions of length and width of the finite feature measures 500 microns or less.

35. A method as in any of the previous embodiments, wherein the feature comprises a line width ranging from line width ranging from 5 μm and 100 μm.

36. A method as in any of the previous embodiments, wherein the feature comprises a line width ranging from line width ranging from 10 μm and 50 μm.

37. A method as in any of the previous embodiments, wherein the solid metal powder is deposited as a high velocity aerosol beam such that the solid particles deform as they impact the substrate to generate the finite feature on the substrate.

38. A method as in any of the previous embodiments, wherein the aerosol beam at the exit opening has a velocity ranging between 200 m/s and 1000 m/s.

39. A method as in any of the previous embodiments, wherein cold spraying the aerosolized powder comprises: inputting a carrier gas into a deposition head; the carrier gas carrying the aerosolized powder; inputting an accelerator gas into a deposition head to accelerate the metal particles; wherein the deposition head comprises a nozzle at an output of the deposition head; wherein the nozzle has an entrance opening and an exit opening; and integrating the accelerator gas with the carrier gas to drive the carrier gas out of the exit opening of the nozzle to form the high velocity aerosol beam.

40. A method as in any of the previous embodiments, further comprising: heating the deposition head to a predetermined temperature in order to compensate for the drop in temperature of accelerator and carrier gas as it goes through the nozzle.

41. A method as in any of the previous embodiments: wherein the deposition head comprises a first channel configured to deliver the carrier gas from the input along at least a length of the deposition head; wherein the first channel has an exit port that is spaced apart from the entrance opening of the nozzle to form a gap between the exit port and the entrance opening of the nozzle; and wherein the deposition head comprises a second channel configured to deliver the accelerator gas to the gap to integrate with the carrier gas.

42. A method as in any of the previous embodiments, wherein the finite feature comprises a conductive feature on the substrate.

43. A method as in any of the previous embodiments: wherein the first channel is positioned substantially concentric with the nozzle; and wherein the second channel is configured to deliver the accelerator gas into the gap at an angle with respect to the carrier gas.

44. A method as in any of the previous embodiments: wherein the second channel forms a conical channel leading into the gap; and wherein the exit port of the first channel terminates at an apex of the conical channel.

45. A method as in any of the previous embodiments, wherein the aerosol beam is focused to a diameter that is significantly smaller than the diameter of the exit opening of the bore

46. A method as in any of the previous embodiments, wherein the aerosol beam is substantially collimated as it exits the exit opening of the nozzle.

47. A method as in any of the previous embodiments; wherein the aerosol beam is shaped in said bore prior to exiting the exit opening of the nozzle.

48. A method as in any of the previous embodiments, wherein the finite feature comprises a deformable solid.

49. A method as in any of the previous embodiments, wherein the finite feature comprises a polymer.

50. A method as in any of the previous embodiments, wherein the polymer acts as an insulator.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE I
SUBSTRATE AND METAL COMPATIBILITY

| Substrate | | | |
|---|---|---|---|
| material | Tin | Aluminum | Copper |
| Glass | Yes | Yes | Yes |
| Silicon | Yes | Yes | Yes |
| BT | Yes | Yes | No |
| PEEK | No | Yes | Yes |
| Kapton | Yes | Yes | No |
| Teflon | No | Yes | Yes |
| PES | No | Yes | Yes |
| LCP | No | Yes | Yes |
| Teslin | No | No | Yes |
| FR4 | No | Yes | No |
| Mylar | No | Yes | Yes |

What is claimed is:

1. A micro cold spray direct-write system configured for deposition of solid particles on a substrate, comprising:
a deposition head;
a carrier gas supply line coupled to an input of the deposition head;
wherein the carrier gas supply line is configured to carry aerosolized precursor material comprising solid particles; and
an accelerator gas supply line coupled to the deposition head, the accelerator gas supply line configured to carry an accelerator gas to the deposition head;
wherein the deposition head comprises a nozzle at an output of the deposition head;
wherein the nozzle has an entrance opening and an exit opening;
wherein the accelerator gas is configured to drive the carrier gas out of the exit opening of the nozzle as a high velocity aerosol beam such that the solid particles deform as they impact the substrate to generate a finite feature on the substrate.

2. A system as recited in claim 1:
wherein the deposition head comprises a first channel configured to deliver the carrier gas from the input along at least a length of the deposition head;
wherein the first channel has an exit port that is spaced apart from the entrance opening of the nozzle to form a gap between the exit port and the entrance opening of the nozzle; and
wherein the deposition head comprises a second channel configured to deliver the accelerator gas to the gap to integrate with the carrier gas.

3. A system as recited in claim 1:
wherein the particles comprise a metallic composition; and
wherein the finite feature comprises a conductive feature on the substrate.

4. A system as recited in claim 3, wherein the feature comprises a line having a width ranging from 1 μm to 500 μm.

5. A system as recited in claim 4, wherein the feature comprises a line having a width ranging from 5 μm and 100 μm.

6. A system as recited in claim 5, wherein the feature comprises a line having a width ranging from 10 μm and 50 μm.

7. A system as recited in claim 1, wherein the aerosol beam at the exit opening has a velocity ranging between 200 m/s and 1000 m/s.

8. A system as recited in claim 2:
wherein the first channel is positioned substantially concentric with the nozzle; and
wherein the second channel is configured to deliver the accelerator gas into the gap at an angle with respect to the carrier gas.

9. A system as recited in claim 8:
wherein the second channel forms a conical channel leading into the gap; and
wherein the exit port of the first channel terminates at an apex of the conical channel.

10. A system as recited in claim 2:
wherein the nozzle comprises a tapered converging bore; and
wherein the entrance opening of the nozzle has a larger diameter than the diameter of the exit opening.

11. A system as recited in claim 10:
wherein the nozzle comprises a tapered converging bore leading from the entrance opening of the nozzle; and
wherein the tapered converging bore is follow by a substantially constant diameter bore leading to the exit opening of the nozzle.

12. A system as recited in claim 10, wherein the diameter of the aerosol beam is focused to a diameter that is significantly smaller than the diameter of the exit opening of the bore.

13. A system as recited in claim 10, wherein the aerosol beam is substantially collimated as it exits the exit opening of the nozzle.

14. A system as recited in claim 13; wherein the aerosol beam is shaped in said bore prior to exiting the exit opening of the nozzle.

15. A system as recited in claim 2, further comprising:
a heating element disposed adjacent the first and second channels;
wherein the heating element is configured to heat the carrier and accelerator gas to a predetermined temperature to compensate for a drop in temperature of carrier and accelerator gas as it is accelerated through the nozzle.

16. A micro cold spray direct-write deposition head configured for deposition of solid particles on a substrate, comprising:
a first input for receiving a carrier gas;
wherein the carrier gas comprises an aerosolized precursor material comprising solid particles;
a second input for receiving an accelerator gas; and
a nozzle at an output of the deposition head;
wherein the nozzle has an entrance opening and an exit opening;
wherein the accelerator gas is configured to drive the carrier gas out of the exit opening of the nozzle as a high velocity aerosol beam, such that the solid particles deform as they impact the substrate to generate a finite feature on the substrate.

17. A deposition head as recited in claim 16, further comprising:
a first channel configured to deliver the carrier gas from the input along at least a length of the deposition head;
wherein the first channel has an exit port that is spaced apart from the entrance opening of the nozzle to form a gap between the exit port and the entrance opening of the nozzle; and
a second channel configured to deliver the accelerator gas to the gap to integrate with the carrier gas.

18. A deposition head as recited in claim 16:
wherein the particles comprise a metallic composition; and
wherein the feature comprises a conductive feature on the substrate.

19. A deposition head as recited in claim 18, wherein the feature comprises a line having a width ranging from 1 μm to 200 μm.

20. A deposition head as recited in claim 19, wherein the feature comprises a line having a width ranging from 5 μm and 100 μm.

21. A deposition head as recited in claim 20, wherein the feature comprises a line having a width ranging from 10 μm and 50 μm.

22. A deposition head as recited in claim 16, wherein the aerosol beam at the exit opening has a velocity ranging between 200 m/s and 1000 m/s.

23. A deposition head as recited in claim 22:
wherein the first channel is positioned substantially concentric with the nozzle; and
wherein the second channel is configured to deliver the accelerator gas into the gap at an angle with respect to the carrier gas.

24. A deposition head as recited in claim 23:
wherein the second channel forms a conical channel leading into the gap; and
wherein the exit port of the first channel terminates at an apex of the conical channel.

25. A deposition head as recited in claim 17:
wherein the nozzle comprises a tapered converging bore; and
wherein the entrance opening of the nozzle has a larger diameter than the diameter of the exit opening.

26. A deposition head as recited in claim 25:
wherein the nozzle comprises a tapered converging bore leading from the entrance opening of the nozzle; and
wherein the tapered converging bore is followed by a substantially constant diameter bore leading to the exit opening of the nozzle.

27. A deposition head as recited in claim 25, wherein the aerosol beam is focused to a diameter that is significantly smaller than the diameter of the exit opening of the bore.

28. A deposition head as recited in claim 25, wherein the aerosol beam is substantially collimated as it exits the exit opening of the nozzle.

29. A deposition head as recited in claim 28; wherein the aerosol beam is shaped in said bore prior to exiting the exit opening of the nozzle.

30. A deposition head as recited in claim 17, further comprising:
a heating element disposed adjacent the first and second channels;
wherein the heating element is configured to heat the carrier and accelerator gas to a predetermined temperature to compensate for a drop in temperature of carrier and accelerator gas as it is accelerated through the nozzle.

31. A deposition head as recited in claim 16, wherein the finite feature comprises a deformable solid.

32. A deposition head as recited in claim 16, wherein the finite feature comprises a polymer.

33. A deposition head as recited in claim 32, wherein the polymer acts as an insulator.

34. A method for depositing an aerosolized powder of solid metallic particles on a substrate for printed circuit applications, comprising:
cold spraying the aerosolized powder onto the substrate to form a finite feature;
wherein at least one of the dimensions of length and width of the finite feature measures 500 microns or less.

35. A method as recited in claim 34, wherein the feature comprises a line width ranging from line width ranging from 5 μm and 100 μm.

36. A method as recited in claim 35, wherein the feature comprises a line width ranging from line width ranging from 10 μm and 50 μm.

37. A method as recited in claim 34, wherein the solid metal powder is deposited as a high velocity aerosol beam such that the solid particles deform as they impact the substrate to generate the finite feature on the substrate.

38. A method as recited in claim 37, wherein the aerosol beam at the exit opening has a velocity ranging between 200 m/s and 1000 m/s.

39. A method as recited in claim 34, wherein cold spraying the aerosolized powder comprises:
inputting a carrier gas into a deposition head;
the carrier gas carrying the aerosolized powder;
inputting an accelerator gas into a deposition head to accelerate the metal particles;
wherein the deposition head comprises a nozzle at an output of the deposition head;
wherein the nozzle has an entrance opening and an exit opening; and
integrating the accelerator gas with the carrier gas to drive the carrier gas out of the exit opening of the nozzle to form the high velocity aerosol beam.

40. A method as recited in claim 39, further comprising:
heating the deposition head to a predetermined temperature in order to compensate for the drop in temperature of accelerator and carrier gas as it goes through the nozzle.

41. A method as recited in claim 39:
wherein the deposition head comprises a first channel configured to deliver the carrier gas from the input along at least a length of the deposition head;
wherein the first channel has an exit port that is spaced apart from the entrance opening of the nozzle to form a gap between the exit port and the entrance opening of the nozzle; and
wherein the deposition head comprises a second channel configured to deliver the accelerator gas to the gap to integrate with the carrier gas.

42. A method as recited in claim 37, wherein the finite feature comprises a conductive feature on the substrate.

43. A method as recited in claim 41:
wherein the first channel is positioned substantially concentric with the nozzle; and
wherein the second channel is configured to deliver the accelerator gas into the gap at an angle with respect to the carrier gas.

44. A method as recited in claim 43:
wherein the second channel forms a conical channel leading into the gap; and
wherein the exit port of the first channel terminates at an apex of the conical channel.

45. A method as recited in claim 39, wherein the aerosol beam is focused to a diameter that is significantly smaller than the diameter of the exit opening of the bore

46. A method as recited in claim 39, wherein the aerosol beam is substantially collimated as it exits the exit opening of the nozzle.

47. A method as recited in claim 46, wherein the aerosol beam is shaped in said bore prior to exiting the exit opening of the nozzle.

48. A method as recited in claim 34, wherein the finite feature comprises a deformable solid.

49. A method as recited in claim 34, wherein the finite feature comprises a polymer.

50. A method as recited in claim 49, wherein the polymer acts as an insulator.
